(19) United States
(12) Patent Application Publication
(10) Pub. No.: US 2023/0064639 A1
(43) Pub. Date: Mar. 2, 2023

(54) MICRO-LED PIXEL ARRANGEMENT STRUCTURE, ARRANGEMENT METHOD, AND DISPLAY PANEL

(71) Applicant: KONKA GROUP CO., LTD., Shenzhen (CN)

(72) Inventors: WENKUI ZHONG, SHENZHEN (CN); WEIHAN LIN, SHENZHEN (CN); JIANXI HE, SHENZHEN (CN); MEIHUI YANG, SHENZHEN (CN)

(21) Appl. No.: 17/758,689

(22) PCT Filed: Jan. 13, 2020
(86) PCT No.: PCT/CN2020/071624

§ 371 Date: Jul. 12, 2022

(51) Int. Cl. H01L 25/16

(52) U.S. Cl. CPC H01L 25/167

(57) ABSTRACT

Disclosed are a Micro-LED pixel arrangement structure, an arrangement method, and a display panel. The pixel arrangement structure comprises a plurality of pixel groups, each comprises a plurality of sub-pixels. The arrangement directions of the sub-pixels in the plurality of pixel groups on the leftmost column and in the plurality of pixel groups on the rightmost column are perpendicular to the arrangement direction of the sub-pixels in other pixel groups on the first row or the last row. The arrangement directions of the sub-pixels in the pixel groups on the leftmost column and in the pixel groups on the rightmost column in the Micro-LED pixel arrangement structure are perpendicular to the arrangement directions of the sub-pixels in other pixel groups on the first row or the last row, thereby avoiding edge color shift and improving the display quality.

### CROSS-REFERENCES TO RELATED APPLICATIONS

This application is a national stage application of PCT Patent Application No. PCT/CN2020/071624, filed on Jan. 13, 2020, the content of all of which is incorporated herein by reference.

### FIELD OF THE INVENTION

The present disclosure generally relates to the technical field of semi-conductor displaying, and more particularly, to a Micro-LED pixel arrangement structure, an arrangement method, and a display panel

### BACKGROUND

With the continuous development of display technology, the Micro-LED technology, that is, an LED micro-scaling and matrixing technology, is a new generation of display technology, refers to an LED array having a micro size and in a high-density integrated on one chip, for example, each pixel on the LED display screen is addressable, being able to be driven to illuminate individually, which may be viewed as a micro-scale of an outdoor LED display screen, while a distance between two pixels is reduced from a millimeter level to a micron level; wherein each pixel unit in a Micro-LED display panel comprises three sub-pixels of Red-Green-Blue (RGB), and each sub-pixel is arranged repeatedly according to an order of Red, Green, and Blue (RGB). At the same time, the Micro-LED display panel is formed by splicing a plurality of display modules, and the sub-pixels of Red-Green-Blue in each module are protected by a glue-sealing layer, so as to prevent the Micro-LED display screen from being damaged by external force.

However, the display modules in the prior art, as shown in FIG. 1, has each sub-pixel arranged in an order of Red, Green, and Blue (RGB) from left to right, thus each module has at least two (one module has four) adjacent sub-pixels in a same color (that is, in FIG. 1, all R-pixels in the leftmost column and all B-pixels in the rightmost column), forming an edge color shift. Also, shown as FIG. 2, since the Micro-LED display panel is formed by splicing a plurality of display modules, a splicing position in each module will have an edge color shift, affecting viewing experience.

Therefore, the existing technology needs to be improved and developed.

### BRIEF SUMMARY OF THE INVENTION

According to a plurality of defects listed above in the prior art, the purpose of the present disclosure is to provide a Micro-LED pixel arrangement structure, an arrangement method, and a display panel, aiming to overcome the defects of the display module generating the edge color shift in existing Micro-LED display panel.

In order to achieve the object described above, the technical solution of the present disclosure is as follows:

A Micro-LED pixel arrangement structure comprising: a plurality of pixel groups arranged in an array, each pixel group comprises a plurality of sub-pixels, and in the pixel arrangement structure an arrangement direction of each sub-pixel in the plurality of pixel groups located on a leftmost column and in the plurality of pixel groups located on a rightmost column is perpendicular to an arrangement direction of each sub-pixel in other pixel groups located on a first row or on a last row.

Further, in the Micro-LED pixel arrangement structure, the plurality of sub-pixels comprises: a first sub-pixel, a second sub-pixel and a third sub-pixel.

Further, in the Micro-LED pixel arrangement structure, the first sub-pixel, the second sub-pixel, and the third sub-pixel in the plurality of pixel groups located on the leftmost column have a same distance away from a leftmost side of the Micro-LED pixel arrangement structure; the first sub-pixel, the second sub-pixel, and the third sub-pixel in the plurality of pixel groups located on the rightmost column have a same distance away from a rightmost side of the Micro-LED pixel arrangement structure.

Further, in the Micro-LED pixel arrangement structure, each sub-pixel in the plurality of pixel groups located on the leftmost column is arranged close to the left side, and each sub-pixel in the plurality of pixel groups located on the rightmost column is arranged close to the right side.

Further, in the Micro-LED pixel arrangement structure, each sub-pixel in the plurality of pixel groups located on the leftmost column and in the plurality of pixel groups located on the rightmost column is arranged at an interval from top down respectively.

Further, in the Micro-LED pixel arrangement structure, the first sub-pixel, the second sub-pixel, and the third sub-pixel are in a circular shape or a polygonal shape with a side number no less than four.

Further, in the Micro-LED pixel arrangement structure, major axis of the first sub-pixel, the second sub-pixel, and the third sub-pixel in the plurality of pixel groups located on the leftmost column and the plurality of pixel groups located on the rightmost column are parallel to a horizontal direction.

Further, in the Micro-LED pixel arrangement structure, the first sub-pixel, the second sub-pixel and the third sub-pixel are in different colors, the first sub-pixel, the second sub-pixel, and the third sub-pixel are one of a red sub-pixel, a green sub-pixel, and a blue sub-pixel. Further, in the Micro-LED pixel arrangement structure, the first sub-pixel, the second sub-pixel, and the third sub-pixel in other pixel groups located on the first row or the last row are arranged at an interval from left to right.

Further, in the Micro-LED pixel arrangement structure, major axis of the first sub-pixel, the second sub-pixel, and the third sub-pixel in other pixel groups located in middle of the Micro-LED pixel arrangement structure are parallel to a horizontal direction or a vertical direction.

An arrangement method of the Micro-LED pixel arrangement structure, which comprises: arranging an arrangement direction of each sub-pixel in a plurality of pixel groups located on a leftmost column and in a plurality of pixel groups located on a rightmost column perpendicular to an arrangement direction of each sub-pixel in other pixel groups located on a first row or on a last row, the pixel groups are arranged in an array.

Further, the arrangement method of the Micro-LED pixel arrangement structure comprises: adjusting a distance between each sub-pixel in the plurality of pixel groups located on the leftmost column and a leftmost side of the Micro-LED pixel arrangement structure to be consistent;

adjusting a distance between each sub-pixel in the plurality of pixel groups located on the rightmost column and a rightmost side of the Micro-LED pixel arrangement structure to be consistent.

Further, the arrangement method of the Micro-LED pixel arrangement structure comprises: arranging each sub-pixel in the plurality of pixel groups located on the leftmost column and in the plurality of pixel groups located on the rightmost column in an interval from top down respectively.

A display panel, which comprises the Micro-LED pixel arrangement structure stated above. Beneficial effect: The present disclosure provides a Micro-LED pixel arrangement structure, an arrangement method and a display panel. The Micro-LED pixel arrangement structure comprises a plurality of pixel groups, each comprises a plurality of sub-pixels, and in the pixel arrangement structure an arrangement direction of each sub-pixel in the plurality of pixel groups located on the leftmost column and in the plurality of pixel groups located on the rightmost column is perpendicular to an arrangement direction of each sub-pixel in other pixel groups located on the first row or on the last row. By arranging the arrangement direction of each sub-pixel in the plurality of pixel groups located on the leftmost column and in the plurality of pixel groups located on the rightmost column in the Micro-LED pixel arrangement structure perpendicular to the arrangement direction of each sub-pixel in other pixel groups located on the first row or on the last row, the edge color shift in the pixel arrangement structure is avoided, thereby improving a display quality of the Micro-LED display panel.

### BRIEF DESCRIPTION OF THE DRAWINGS

FIG. 1 illustrates a schematic diagram on a pixel arrangement manner of a display module in a Micro-LED display panel in the prior art;

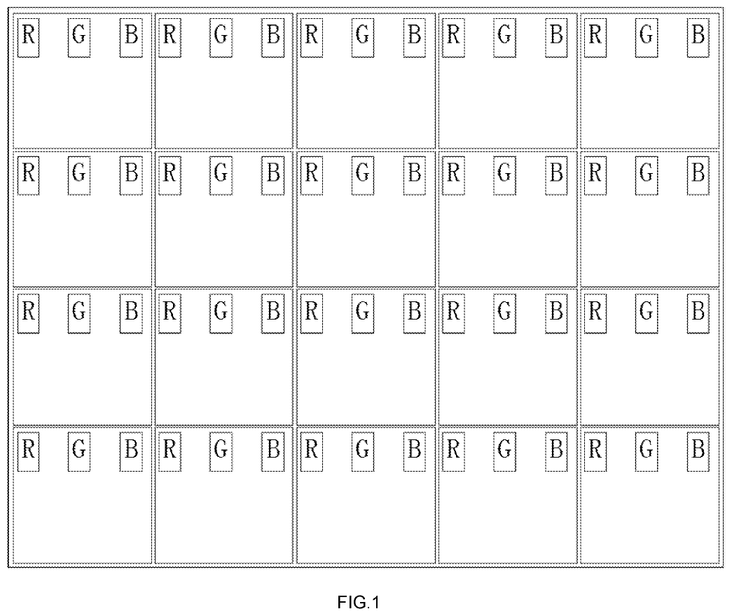

FIG. 2 illustrates a schematic structural diagram on a Micro-LED display panel in the prior art;

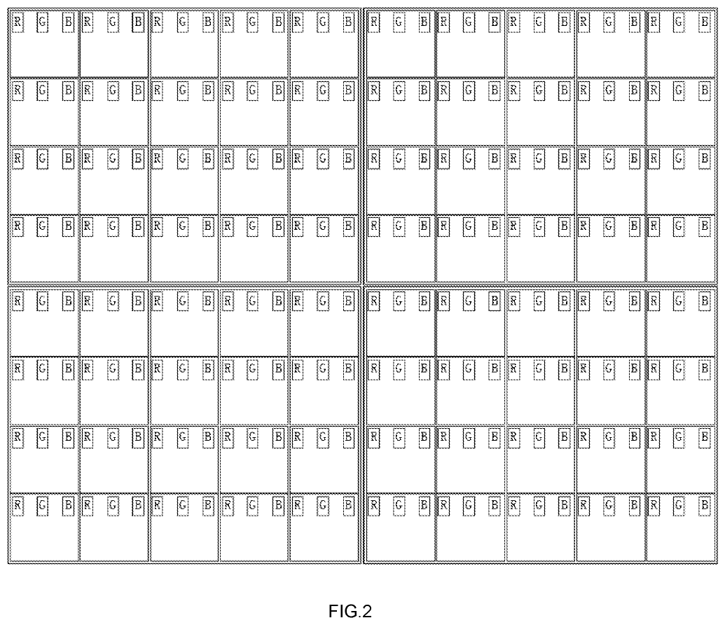

FIG. 3 illustrates a schematic structural diagram on a Micro-LED pixel arrangement structure according to an embodiment of the present disclosure;

FIG. 4 illustrates a schematic structural diagram on a Micro-LED pixel arrangement structure according to another embodiment of the present disclosure;

FIG. 5 illustrates a schematic diagram on a Micro-LED pixel arrangement structure when a sub-pixel is circular according to an embodiment of the present disclosure;

FIG. 6 is a schematic structural diagram on a display panel according to an embodiment of the present disclosure.

### DETAILED DESCRIPTION

In order to make the objectives, technical schemes and benefits more explicit, further description to illustrate the present disclosure will be made in details with reference to the accompanying drawings and embodiments. It should be understood that the specific embodiments described herein are only used to explain the present disclosure, and are not intended to limit the scope of the present disclosure. All directional indications in the embodiments of the present disclosure, (including upper, lower, left, right, front, back, and more) are applied only to explaining a relative positional relationship, or a motion situation between each component in a certain specific structure (shown as the drawings), and if the certain specific structure changes, the directional indications will also change accordingly.

In a scope of the embodiments and the patent application, the terms “a” and “the” may generally refer to one or a plurality of, unless there is a specific limitation to the articles in the context.

In addition, descriptions of the terms “first”, “second” and the like in the embodiments of the present disclosure are used for descriptive purposes only, instead of being understood as indicating or implying relative importance or implicitly indicating a number of an indicated technical feature. Thus, a feature defined with “first” or “second” may comprise at least one of the present features explicitly or implicitly. In addition, the technical solutions between the embodiments may be combined with each other, but it must be on a basis of being implemental by those of ordinary skills in the art.

When a combination of the technical solutions is contradictory or cannot be implemented, it should be considered that such a combination of the technical solutions is not present, thus not within the protection scope of the present disclosure.

Further descriptions to illustrate the present disclosure are made in details with reference to the accompanying drawings and embodiments below. .

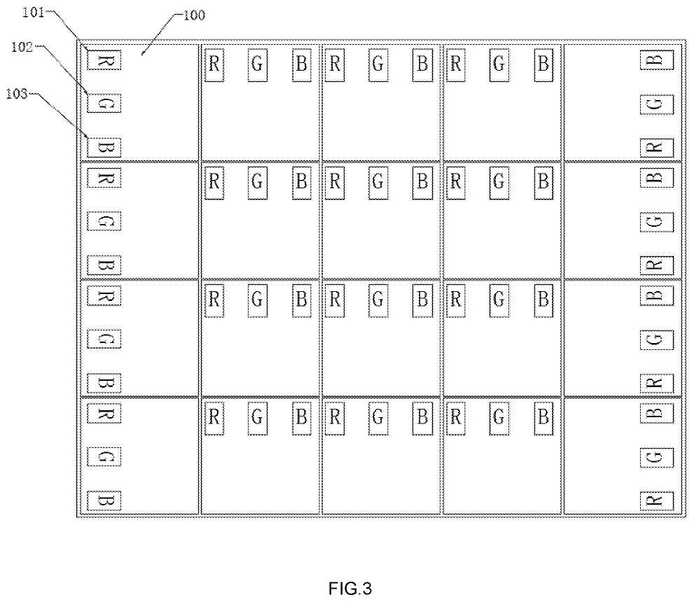

FIG. 3 is a schematic structural diagram on a Micro-LED pixel arrangement structure according to an embodiment of the present disclosure. The Micro-LED pixel arrangement structure comprises a plurality of pixel groups 100 arranged in an array, and each pixel group 100 comprises a plurality of sub-pixels. Wherein an arrangement direction of each sub-pixel in the plurality of pixel groups located on a leftmost column and in the plurality of pixel groups located on a rightmost column in the Micro-LED pixel arrangement structure is perpendicular to an arrangement direction of each sub-pixel in other pixel groups located on a first row or on a last row. Specifically, the plurality of sub-pixels comprises: a first sub-pixel 101, a second sub-pixel 102, and a third sub-pixel 103, the arrangement direction of the first sub-pixel 101, the second sub-pixel 102, and the third sub-pixel 103 in the plurality of pixel groups located on the leftmost column and in the plurality of pixel groups located on the rightmost column is perpendicular to the arrangement direction of the first sub-pixel 101, the second sub-pixel 102, and the third sub-pixel 103 in other pixel groups located on the first row or on the last row. Shown as FIG. 3, the arrangement direction of the first sub-pixel 101, the second sub-pixel 102, and the third sub-pixel 103 in the plurality of pixel groups 100 located on the leftmost column and the rightmost column is in a vertical direction, while the arrangement direction of the first sub-pixel 101, the second sub-pixel 102, and the third sub-pixel 103 in the plurality of pixel groups 100 located on an uppermost row and on a lowermost row is in a horizontal direction. Such an arrangement manner makes the arrangement directions of the pixel groups located on four sides of the pixel arrangement structure are perpendicular to each other, and the first sub-pixel 101, the second sub-pixel 102, and the third sub-pixel 103 in the pixel groups located on four sides are all arranged in an interval, thus an edge color shift resulted from a same kind of sub-pixels appearing on a same side is avoided.

It should be noted that, the leftmost, the rightmost, the uppermost row, and the lowermost row appeared in the description stated above are with reference to the positions shown in FIG. 3. It should be understood that the above solution focuses on the pixel groups arranged in a regular manner, changing the direction of the pixel groups having a same color of sub-pixels on the edge to be perpendicular to an arrangement direction of the pixel groups in middle, thus making an edge of the pixel arrangement structure not be composed by sub-pixels with same color, and the directions stated above are described in a specific structure. If the specific structure changes, the directional indication will also be changed accordingly and correspondingly. Therefore, it is also within the scope of protection of the present disclosure.

Continue referring to FIG. 3, the first sub-pixel 101, the second sub-pixel 102, and the third sub-pixel 103 are one of a red sub-pixel (R), a green sub-pixel (G), and a blue sub-pixel (B), and the first sub-pixel 101, the second sub-pixel 102, and the third sub-pixel 103 are in different colors. In an embodiment, the first sub-pixel 101, the second sub-pixel 102, and the third sub-pixel 103 are sub-pixels of R, G, B respectively or G, R,

B sub-pixels, or B, R, G sub-pixels, each one is fine. The embodiments in the present disclosure are taking the first sub-pixel 101 as a red sub-pixel, the second sub-pixel 102 as a green sub-pixel, and the third sub-pixel 103 as a blue sub-pixel for an example.

In the present embodiment, the distances from the first sub-pixel 101, the second sub-pixel 102, and the third sub-pixel 103 in the plurality of pixel groups 100 located on the leftmost column in the Micro-LED pixel arrangement structure to a leftmost side of the Micro-LED pixel arrangement structure are the same; the distances from the first sub-pixel 101, the second sub-pixel 102, and the third sub-pixel 103 in the plurality of pixel groups 100 located on the rightmost column in the Micro-LED pixel arrangement structure to a rightmost side of the Micro-LED pixel arrangement structure are the same.

The three sub-pixels in the pixel group 100 located on the leftmost column are arranged in parallel to each other in a horizontal direction, then in order to meet a uniformity rate of edge light emission, the first sub-pixel 101, the second sub-pixel 102, and the third sub-pixel 103 in the pixel group 100 located on the leftmost column shall have a consistent distance to the leftmost edge; the first sub-pixel 101, the second sub-pixel 102, and the third sub-pixel 103 in the pixel group 100 located on the rightmost column shall have a consistent distance to the rightmost edge, which may ensure that the three sub-pixels on the edge emit light uniformly. It should be noted that the distances from the three sub-pixels in the pixel groups 100 located on the leftmost column and the rightmost column to the leftmost edge and the rightmost edge are consistent, but not fixed, and a distance of a corresponding interval can of course be changed depending on actual manufacture.

Each sub-pixel in the plurality of pixel groups 100 located on the leftmost column is arranged close to a left side, and each sub-pixel in the plurality of pixel groups located on the rightmost column is arranged close to a right side. That is, the first sub-pixel 101, the second sub-pixel 102, and the third sub-pixel 103 in the pixel groups 100 located on the leftmost column are arranged close to the left side, and the first sub-pixel 101, the second sub-pixel 102, and the third sub-pixel 103 in the pixel groups 100 located on the rightmost column are arranged close to the right side, so as to ensure a consistency of edge-emitting light.

Further, the sub-pixels in the pixel groups 100 located on the leftmost column or in the pixel groups 100 located on the rightmost column are arranged at an interval from top down respectively. In an embodiment, the first sub-pixel 101, the second sub-pixel 102, and the third sub-pixel 103 in the pixel groups 100 located on the leftmost column are arranged from top down respectively, while the third sub-pixel 103, the second sub-pixel 102, and the first sub-pixel 101 in the pixel groups 100 located on the rightmost column are arranged at an interval from top down respectively. It should be understood that an order in which each sub-pixel is arranged from top down is not limited, as long as it is satisfied that each sub-pixel is in an interval from top down.

Specifically, the pixel group 100 is rectangular, wherein the first sub-pixel 101, the second sub-pixel 102, and the third sub-pixel 103 form the pixel group 100. In an actual production when designing a PCB welding plate, in order to improve efficiency, the first sub-pixel 101, the second sub-pixel 102, and the third sub-pixel 103 are designed in a pixel group 100 as a whole to facilitate welding. Therefore, each pixel group 100 comprises a first sub-pixel 101, a second sub-pixel 102, and a third sub-pixel 103 inside.

The first sub-pixel 101, the second sub-pixel 102, and the third sub-pixel 103 in the pixel group located on the leftmost side and in the pixel group located on the rightmost side in the present disclosure are arranged at an interval, such an arrangement manner makes that the sub-pixels in the pixel group located on the left column and the right column have no single color sub-pixels appear on the same side. Comparing with a pixel arrangement in the prior art, the present disclosure needs only to change an arrangement manner of the sub-pixels in the pixel groups located on the left column and the right column of the Micro-LED pixel arrangement structure, instead of adjusting the pixel groups and the sub-pixels in other positions, or adjusting other structures. Such an arrangement manner can avoid effectively the edge color shift generated from the single type pixels locating on the same side in the Micro-LED pixel arrangement structure.

It should be noted that, continue referring to FIG. 3, the Micro-LED pixel arrangement structure in the present disclosure, comparing to the arrangement of the sub-pixels in the prior art, rotates the pixel groups and sub-pixels therein located on the left column and the right column to obtain the present arrangement effect, for example, the rotation is 90° in a clockwise direction or a counterclockwise direction, and of course, a rotation angle herein is only a visual manner comparing to the arrangement manner in the prior art. While in an actual production process, it is possible to achieve the arrangement manner of the pixel groups and each sub-pixel by taking the transfer technology adopted during a prior Micro-LED process, for example, applying a mass transfer technology in the Micro-LED process. The mass transfer technology, in a simple word, is a process manner of welding a plurality of three-primary-color LED micro-grains of red-green-blue uniformly onto a circuit substrate (the circuit substrate is divided into an AM (Active Matrix) drive and a PM (Passive Matrix) drive according to a circuit drive manner, wherein AM corresponds to a TFT glass substrate, PM corresponds to a PCB substrate), according to a plurality of necessary specifications in optics and electrics, and has an allowable process failure rate of a few tens of parts per million. A plurality of specific transfer steps are prior art, and will not be described here in the present disclosure.

As a further solution, the first sub-pixel 101, the second sub-pixel 102, and the third sub-pixel 103 in the present disclosure may be circular or polygonal with a side number no less than four.

Taking a rectangular sub-pixel as an example, major axis of the first sub-pixel 101, the second sub-pixel 102, and the third sub-pixel 103 in the plurality of pixel groups 100 located on the leftmost column and in the plurality of pixel groups located on the rightmost column are parallel to a horizontal direction. That is, the major axis of the first sub-pixel 101, the second sub-pixel 102, and the third sub-pixel 103 in the pixel groups 100 located on the leftmost column and the rightmost column are arranged in horizontal, and three sub-pixels are arranged in parallel in the horizontal direction, accordingly, minor axis, which are perpendicular to the major axis, of the first sub-pixel 101, the second sub-pixel 102, and the third sub-pixel 103 located on the leftmost column and the rightmost column are perpendicular to the horizontal direction, and parallel to a vertical direction.

As a further solution, in the Micro-LED pixel arrangement structure, the major axis of the first sub-pixel 101, the second sub-pixel 102, and the third sub-pixel 103 in other pixel groups located on the first row or the last row are parallel to a vertical direction; an arrangement direction of the pixel groups 100 in the first row and the pixel groups 100 in the last row are perpendicular to the arrangement direction of the pixel groups 100 located on the leftmost column and the pixel groups 100 located on the rightmost column. Therefore, when the major axis of the three sub-pixels in the pixel groups 100 located on the leftmost column and in the pixel groups 100 located on the rightmost column are parallel to the horizontal direction, the major axis of the first sub-pixel 101, the second sub-pixel 102, and the third sub-pixel 103 in the pixel groups located on the uppermost row and in the pixel groups located on the lowermost row are parallel to the vertical direction. Further, the first sub-pixel 101, the second sub-pixel 102, and the third sub-pixel 103 in the pixel groups 100 located on the first row and the last row are arranged at an interval respectively from left to right, and perpendicular to the first sub-pixel 101, the second sub-pixel 102, and the third sub-pixel 103 in the pixel groups 100 located on the leftmost column and in the pixel groups 100 located on the rightmost column in an arrangement manner.

In an embodiment, continue referencing to FIG. 3, the Micro-LED pixel arrangement structure is a structure of 4*5, the first sub-pixel 101, the second sub-pixel 102, and the third sub-pixel 103 are a red sub-pixel (R), a green sub-pixel (G), and a blue sub-pixel (B) respectively, the major axis of the red sub-pixel (R), the green sub-pixel (G), and the blue sub-pixel (G) in the pixel groups located on the leftmost column of and in the pixel groups located on the rightmost column are parallel to the horizontal direction, while the minor axis thereof are perpendicular to the horizontal direction. Similarly, the major axis of the sub-pixels of red, green and blue in the pixel groups located on the first row and in the pixel groups located on the last row are parallel to the vertical direction, while the minor axis thereof are perpendicular to the vertical direction.

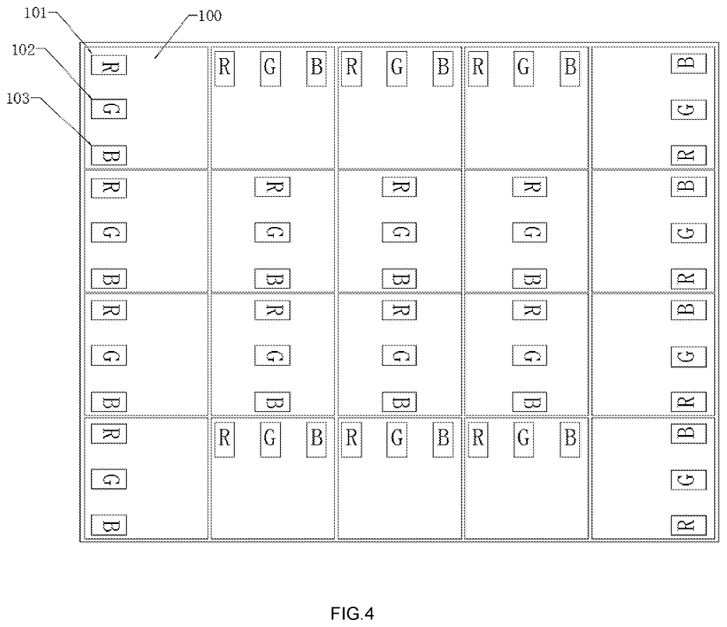

Further, FIG. 4 is a schematic diagram of a Micro-LED pixel arrangement structure according to another embodiment of the present disclosure. The major axis of the first sub-pixel 101, the second sub-pixel 102, and the third sub-pixel 103 in other pixel groups 100 located in a middle of the Micro-LED pixel arrangement structure are parallel to the horizontal direction, as shown in FIG. 4. In other embodiment, the major axis of the red sub-pixel, the green sub-pixel, and the blue sub-pixel in the pixel groups located in the middle may also be parallel to the vertical direction, since the edge color shift is present only at an edge of the pixel arrangement structure instead of in a middle part, thus a pixel arrangement manner in the middle is not limited specifically in the present disclosure.

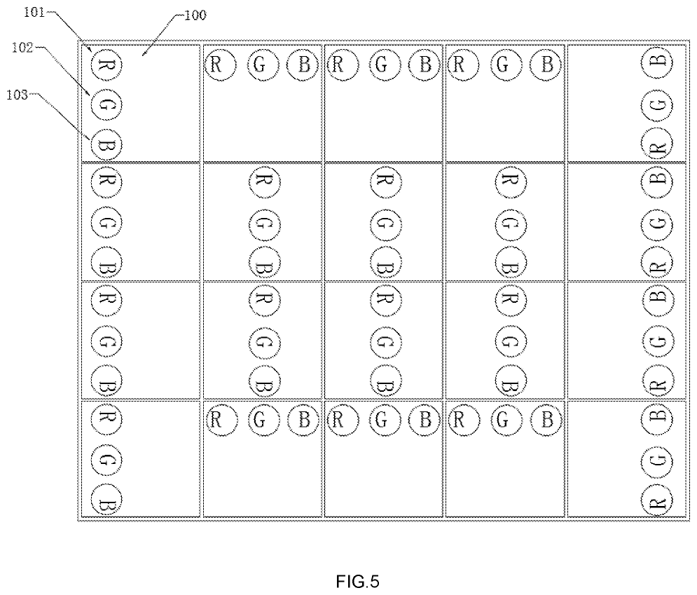

As a further solution, the first sub-pixel 101, the second sub-pixel 102, and the third sub-pixel 103 are rectangular. The present disclosure further provides a new sub-pixel shape, referring to FIG. 5, FIG. 5 illustrates a schematic diagram on a Micro-LED pixel arrangement structure. The shape of the first sub-pixel 101, the second sub-pixel 102, and the third sub-pixel 103 in the pixel group 100 are circular. Of course, in other embodiments, the sub-pixels may be other shapes in addition to the circular shape, and the shape of the sub-pixels stated above is merely illustrative, and there is no limitations to a specific shape as long as a light-emitting function can be met, and the shape may be selected according to an actual requirement.

It should be understood that a definition of the horizontal direction and the vertical direction in the present disclosure is a structure described with a combination of the drawings (e.g., the horizontal direction is a direction parallel to a ground, the vertical direction is a direction perpendicular to a bottom surface), and if the structure changes, the directional indication will also change accordingly.

In addition, the present disclosure further provides an arrangement method of the Micro-LED pixel arrangement structure, which comprises:

S1, arranging an arrangement direction of each sub-pixel in a plurality of pixel groups located on the leftmost column and in a plurality of pixel groups located on the rightmost column perpendicular to an arrangement direction of each sub-pixel in other pixel groups located on the first row or on the last row, all the pixel groups are arranged in an array;

further comprising: adjusting a distance between each sub-pixel in the plurality of pixel groups located on the leftmost column and the leftmost side of the Micro-LED pixel arrangement structure to be consistent;

adjusting a distance between each sub-pixel in the plurality of pixel groups located on the rightmost column and the rightmost side of the Micro-LED pixel arrangement structure to be consistent;

arranging each sub-pixel in the plurality of pixel groups located on the leftmost column and in the plurality of pixel groups located on the rightmost column in an interval from top down respectively.

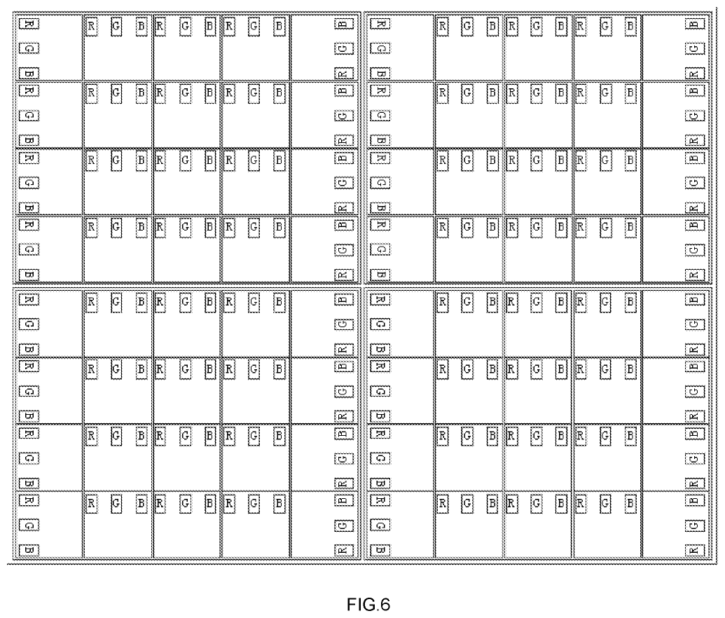

In the present embodiment, each of the pixel groups comprises the first sub-pixel 101, the second sub-pixel 102, and the third sub-pixel 103, by arranging the first sub-pixel 101, the second sub-pixel 102, and the third sub-pixel 103 in the pixel groups located on the leftmost column and the rightmost column to be perpendicular to the first sub-pixel 101, the second sub-pixel 102, and the third sub-pixel 103 in other pixel groups, edge color shift, which is caused by single color sub-pixels appearing in a same edge, is avoided, and a new arrangement method for the Micro-LED pixel arrangement structure is provided. In addition, referring to FIG. 6, FIG. 6 is a schematic structural diagram on a display panel according to an embodiment of the present disclosure. The present disclosure further provides a display panel, which comprises the Micro-LED pixel arrangement structure stated above. Since a detailed description has been stated above on the Micro-LED pixel arrangement structure, thus it will not be repeated here.

All above, the present disclosure provides a Micro-LED pixel arrangement structure, an arrangement method and a display panel. The Micro-LED pixel arrangement structure comprises a plurality of pixel groups, and each pixel group comprises a plurality of sub-pixels, while in the pixel arrangement structure an arrangement direction of each sub-pixel in the plurality of pixel groups located on the leftmost column and in the plurality of pixel groups located on the rightmost column in the pixel arrangement structure is perpendicular to an arrangement direction of each sub-pixel in other pixel groups located on the first row or on the last row. By arranging the arrangement direction of each sub-pixel in the plurality of pixel groups located on the leftmost column and in the plurality of pixel groups located on the rightmost column in the Micro-LED pixel arrangement structure to be perpendicular to the arrangement direction of each sub-pixel in other pixel groups located on the first row or on the last row, the edge color shift is avoided, thereby improving the display quality of the Micro-LED display panel.

Other embodiments of the disclosure will be readily apparent to those skilled in the art upon consideration of the specification and practice of the disclosure disclosed herein. The present disclosure is intended to cover any variations, uses, or adaptations of the disclosure following the general principles of the disclosure and including common general knowledge or customary technical means in the art not disclosed in the present disclosure. The specification and embodiments are considered as exemplary only, while a true scope and spirit of the disclosure are indicated by the claims.

It should be understood that the application of the present disclosure is not limited to the above examples and can be improved or transformed by those skilled in the art based on the above description. All these improvements and transformations should fall within the protection scope of the appended claims of the present disclosure.

What is claimed is:

1. A Micro-LED pixel arrangement structure, comprising:
a plurality of pixel groups arranged in an array, wherein each of the plurality of pixel groups comprises a plurality of sub-pixels, wherein an arrangement direction of each sub-pixel in the plurality of pixel groups located on a leftmost column and in the plurality of pixel groups located on a rightmost column in the Micro-LED pixel arrangement structure is perpendicular to an arrangement direction of each sub-pixel in other pixel groups located on a first row or on a last row.

2. The Micro-LED pixel arrangement structure according to claim 1, wherein the plurality of sub-pixels comprises: a first sub-pixel, a second sub-pixel and a third sub-pixel

3. The Micro-LED pixel arrangement structure according to claim 2, wherein the first sub-pixel, the second sub-pixel, and the third sub-pixel in the plurality of pixel groups located on the leftmost column have a same distance away from a leftmost side of the Micro-LED pixel arrangement structure; and
the first sub-pixel, the second sub-pixel, and the third sub-pixel in the plurality of pixel groups located on the rightmost column have a same distance away from a rightmost side of the Micro-LED pixel arrangement structure.

4. The Micro-LED pixel arrangement structure according to claim 1, wherein each sub-pixel in the plurality of pixel groups located on the leftmost column is arranged close to a left side, and each sub-pixel in the plurality of pixel groups located on the rightmost column is arranged close to a right side.

5. The Micro-LED pixel arrangement structure according to claim 4, wherein the sub-pixels in the plurality of pixel groups located on the leftmost column and in the plurality of pixel groups located on the rightmost column are arranged at an interval from top down respectively.

6. The Micro-LED pixel arrangement structure according to claim 2, wherein the first sub-pixel, the second sub-pixel, and the third sub-pixel are in a circular shape or a polygonal shape with a side number no less than four.

7. The Micro-LED pixel arrangement structure according to claim 3, wherein major axis of the first sub-pixel, the second sub-pixel, and the third sub-pixel in the plurality of pixel groups located on the leftmost column and in the plurality of pixel groups located on the rightmost column are parallel to a horizontal direction.

8. The Micro-LED pixel arrangement structure according to claim 2, wherein the first sub-pixel, the second sub-pixel, and the third sub-pixel are one of a red sub-pixel, a green sub-pixel, and a blue sub-pixel; and wherein the first sub-pixel, the second sub-pixel and the third sub-pixel are different colors.

9. The Micro-LED pixel arrangement structure according to claim 7, wherein the first sub-pixel, the second sub-pixel and the third sub-pixel in other pixel groups located on the first row or the last row are arranged at an interval from left to right.

10. The Micro-LED pixel arrangement structure according to claim 2, wherein major axis of the first sub-pixel, the second sub-pixel, and the third sub-pixel in other pixel groups located in middle in the Micro-LED pixel arrangement structure are parallel to a horizontal direction or a vertical direction.

11. An arrangement method of the a Micro-LED pixel arrangement structure, the method comprising:
arranging an arrangement direction of each sub-pixel in a plurality of pixel groups located on a leftmost column and in a plurality of pixel groups located on a rightmost column to be perpendicular to an arrangement direction of each sub-pixel in other pixel groups located on a first row or on a last row, the pixel groups are arranged in an array.

12. The arrangement method of the Micro-LED pixel arrangement structure according to claim 11, further comprising:
adjusting a distance between each sub-pixel in the plurality of pixel groups located on the leftmost column and a leftmost side of the Micro-LED pixel arrangement structure to be consistent; and
adjusting a distance between each sub-pixel in the plurality of pixel groups located on the rightmost column and a rightmost side of the Micro-LED pixel arrangement structure to be consistent.

13. The arrangement method of the Micro-LED pixel arrangement structure according to claim 11, further comprising: arranging each sub-pixel in the plurality of pixel groups located on the leftmost column and in the plurality of pixel groups located on the rightmost column in an interval from top down respectively.

14. A display panel, comprising the Micro-LED pixel arrangement structure according to claim 1.
